(19) United States
(12) Patent Application Publication
(10) Pub. No.: US 2025/0385660 A1
(43) Pub. Date: Dec. 18, 2025

(54) HYBRID FILTER INCLUDING A BULK ACOUSTIC RESONATOR AND A SOLIDLY-MOUNTED BULK ACOUSTIC RESONATOR

(71) Applicant: Murata Manufacturing Co., Ltd., Nagaokakyo-shi (JP)

(72) Inventors: Andrew Guyette, San Bruno, CA (US); Tetsuya Kimura, San Mateo, CA (US); Patrick Turner, Portola Valley, CA (US)

(21) Appl. No.: 19/227,568

(22) Filed: Jun. 4, 2025

Related U.S. Application Data
(60) Provisional application No. 63/659,683, filed on Jun. 13, 2024.

(51) Int. Cl. H03H 9/56; H03H 7/01; H03H 9/54

(52) U.S. Cl. CPC H03H 9/568; H03H 7/0161; H03H 9/542

(57) ABSTRACT

A bandpass filter is provided that includes series acoustic resonators and shunt acoustic resonators. The shunt acoustic resonators include a first transversely-excited film bulk acoustic resonators (XBAR) that includes a diaphragm comprising a portion of a piezoelectric layer that is over a cavity of the first XBAR and a first interdigital transducer (IDT) on a surface of the piezoelectric layer. The first XBAR is connected between (i) a node directly between a first series acoustic resonator of the plurality of series acoustic resonators and the input port, and (ii) a ground of the bandpass filter. The series and shunt acoustic resonators include one or more solidly-mounted XBARs that includes a portion of a second piezoelectric layer that is solidly mounted over a substrate with a Bragg reflector disposed therebetween.

### CROSS REFERENCE TO RELATED APPLICATIONS

This application claims priority to U.S. Patent Provisional No. 63/659,683, filed Jun. 13, 2024, the entire contents of which are hereby incorporated by reference.

### TECHNICAL FIELD

This disclosure relates to filters including transversely-excited film bulk acoustic resonators (XBARs).

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz.

However, in order to provide the type of high-level performance required by the above-described communications applications, potential loss mechanisms that detract from the performance of the RF filters may need to be addressed. One such loss mechanism is an insertion loss (IL).

### SUMMARY

Aspects of the disclosure includes a bandpass filter such as a hybrid bandpass filter. The hybrid bandpass filter includes a plurality of series acoustic resonators and a plurality of shunt acoustic resonators. More particular, a bandpass filter is provided that includes an input port and an output port; a plurality of series acoustic resonators connected between the input port and the output port; and a plurality of shunt acoustic resonators. In this aspect, the plurality of shunt acoustic resonators includes a first transversely-excited film bulk acoustic resonator (XBAR) that includes a diaphragm comprising a portion of a first piezoelectric layer that is over a cavity of the first XBAR and a first interdigital transducer (IDT) on a surface of the first piezoelectric layer, the first IDT comprising a pair of busbars with interleaved fingers extending therefrom and on the diaphragm. Moreover, the first XBAR is connected between (i) a node directly between a first series acoustic resonator of the plurality of series acoustic resonators and the input port, and (ii) a ground of the bandpass filter, and the plurality of series acoustic resonators and the plurality of shunt acoustic resonators includes at least one solidly-mounted XBAR (SM-XBAR) that includes a portion of a second piezoelectric layer that is solidly mounted over a substrate with a Bragg reflector disposed therebetween and a second IDT on a surface of the second piezoelectric layer, the second IDT comprising a pair of busbars with interleaved fingers extending therefrom and on the second piezoelectric layer.

In another exemplary aspect of the bandpass filter, the plurality of shunt acoustic resonators further includes a second XBAR, the second XBAR includes a diaphragm comprising a portion of a third piezoelectric layer that is over a cavity of the second XBAR and a third IDT on a surface of the third piezoelectric layer, the third IDT comprising a pair of busbars with interleaved fingers extending therefrom and on the diaphragm of the second XBAR, the cavity of the second XBAR being disposed above the substrate or being partially disposed in the substrate, and the second XBAR is connected between (i) a node directly between a last series acoustic resonator of the plurality of series acoustic resonators and the output port, and (ii) the ground of the bandpass filter.

In another exemplary aspect of the bandpass filter, the plurality of series acoustic resonators includes a third XBAR, and the third XBAR includes a diaphragm comprising a portion of a fourth piezoelectric layer that is over a cavity of the third XBAR and a fourth IDT on a surface of the fourth piezoelectric layer, the fourth IDT comprising a pair of busbars with interleaved fingers extending therefrom and on the diaphragm of the third XBAR, the cavity of the third XBAR being disposed above the substrate or being partially disposed in the substrate.

In another exemplary aspect of the bandpass filter, the third XBAR is connected between (i) one of the input port and the output port of the bandpass filter and (ii) a node of the bandpass filter, the node of the bandpass filter being different from the input port and the output port of the bandpass filter.

In another exemplary aspect of the bandpass filter, a quality factor of the first XBAR is greater than a quality factor of the SM-XBAR.

In another exemplary aspect of the bandpass filter, quality factors of the first XBAR and the third XBAR are greater than a quality factor of the SM-XBAR.

In another exemplary aspect of the bandpass filter, a quality factor of the first XBAR is substantially identical to a quality factor of the SM-XBAR.

In another exemplary aspect, the bandpass filter includes a dielectric layer disposed between the substrate of the first XBAR and the first piezoelectric layer, wherein the cavity of the first XBAR is in the dielectric layer.

In another exemplary aspect of the bandpass filter, for each of the plurality of series acoustic resonators and the plurality of shunt acoustic resonators, the piezoelectric layer and the IDT are configured such that a radio frequency signal applied to the IDT excites a primary shear acoustic mode in the piezoelectric layer in which acoustic energy propagates along a direction substantially orthogonal to front and back surfaces of the piezoelectric layer and that is transverse to a direction of an electric field created by the interleaved of fingers.

In another exemplary aspect of the bandpass filter, the first piezoelectric layer is the second piezoelectric layer.

In another exemplary aspect of the bandpass filter, the plurality of series acoustic resonators and the plurality of shunt acoustic resonators are all disposed on a single chip, at least a portion of the plurality of series acoustic resonators have a stack thickness that is smaller than a stack thickness of at least a portion of the plurality of shunt acoustic resonators, and the portion of the plurality of series acoustic resonators includes the at least one SM-XBAR, and the portion of the plurality of shunt acoustic resonators incudes the first XBAR.

In another exemplary aspect of the bandpass filter, the first piezoelectric layer of the first XBAR is thicker than a thickness of the second piezoelectric layer.

In another exemplary aspect of the bandpass filter, the Bragg reflector of the at least one SM-XBAR extends across the single chip in a planar direction and excludes an etched region to form the cavity of the first XBAR.

In another exemplary aspect, a bandpass filter is provided that includes a plurality of bulk acoustic wave resonators comprising a first subset of bulk acoustic wave resonators and a second subset of bulk acoustic wave resonators; a first chip comprising the first subset of bulk acoustic wave resonators; a second chip comprising the second subset of bulk acoustic wave resonators; and a circuit card coupled to the first chip and the second chip and including at least one electrical connection between the first subset of bulk acoustic wave resonators of the first chip and the second subset of bulk acoustic wave resonators of the second chip. In this aspect, the plurality of bulk acoustic wave resonators includes a plurality of series acoustic resonators connected in series between an input and an output of the bandpass filter; and a plurality of shunt acoustic resonators that are each connected, respectively, between ground and a node between a pair of the series acoustic resonators or directly between the ground and a node between one of the series acoustic resonators and either the input or the output. Moreover, the plurality of shunt acoustic resonators includes at least one transversely-excited film bulk acoustic resonator (XBAR) that comprises a first piezoelectric layer including a diaphragm that is over a cavity and a first interdigital transducer (IDT) on a surface of the diaphragm that includes a pair of busbars with interleaved fingers extending therefrom, and the plurality of series acoustic resonators includes at least one solidly-mounted XBAR (SM-XBAR) that includes a second piezoelectric layer that is solidly mounted over a substrate with a Bragg reflector disposed therebetween and a second IDT on a surface of the second piezoelectric layer that includes a pair of busbars with interleaved IDT fingers extending therefrom.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a schematic cross-sectional view of two XBARs illustrating a frequency-setting dielectric layer according to an exemplary aspect.

FIG. 7 shows an example of a filter including only solidly-mounted XBARs (SM-XBARs) according to an exemplary aspect of the disclosure.

FIG. 8 shows an example of a hybrid filter including both SM-XBARs and diaphragm-based XBARs according to an exemplary aspect of the disclosure.

FIG. 9 shows an example a hybrid filter including both SM-XBARs and diaphragm-based XBARs according to an exemplary aspect of the disclosure.

FIG. 10 shows an example of a hybrid filter including both SM-XBARs and diaphragm-based XBARs according to an exemplary aspect of the disclosure.

FIG. 11 shows an example of the hybrid filter including both SM-XBARs and diaphragm-based XBARs according to an exemplary aspect of the disclosure.

FIG. 12 shows an example of the hybrid filter including both SM-XBARs and diaphragm-based XBARs according to an exemplary aspect of the disclosure.

FIGS. 13-14 show a comparison between two simulated performances of the hybrid filters of FIGS. 9 and 11 according to an exemplary aspect of the disclosure.

FIG. 15 shows an example of a hybrid filter including both SM-XBARs and diaphragm-based XBARs according to an exemplary aspect of the disclosure.

FIGS. 16-17 show a comparison between multiple simulated performances of the hybrid filter of FIG. 9 and a filter that uses only SM-XBARs according to an exemplary aspect of the disclosure.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

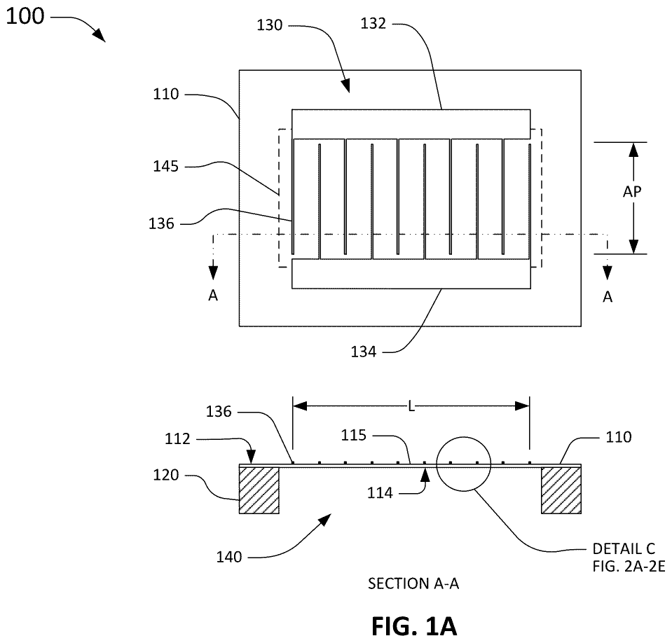

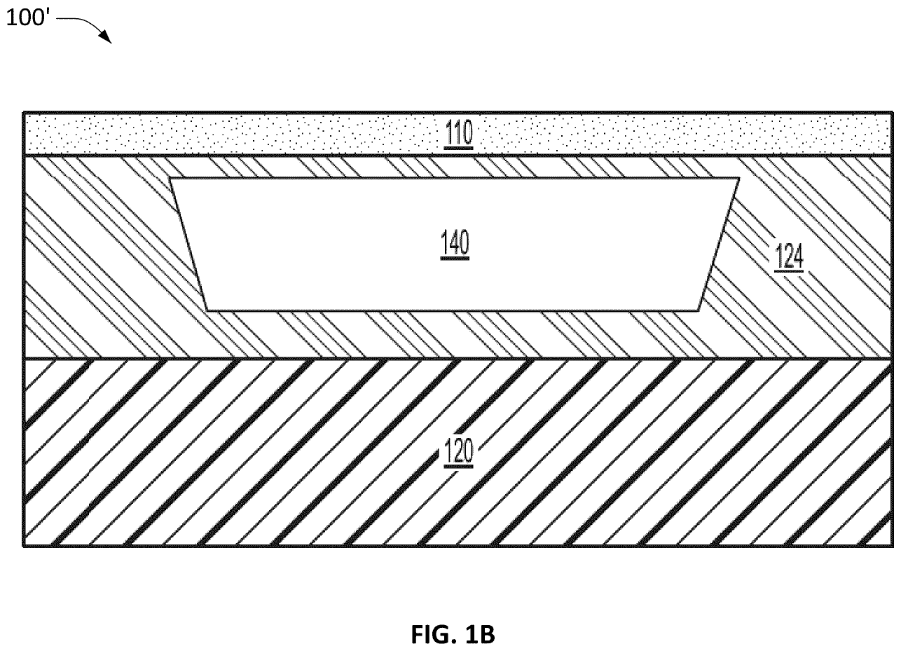

FIG. 1A shows a simplified schematic top view and orthogonal cross-sectional views of a bulk acoustic resonator device, namely a transversely-excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but it takes into account minor variations resulting from manufacturing variances, for example. For example, the “unit pitch” as described below between respective finger units of the IDT is described as being “substantially constant” across the length of the IDT. For purposes of this disclosure, this means that the unit pitch of the IDT is designed to be constant based on the configured manufacturing and metal patterning processes used to form the IDT fingers of the exemplary aspects, but may vary slightly (e.g., within an acceptable threshold or percentage) in practice due to possible manufacturing variances as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90.0) and (0, 128-90.0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

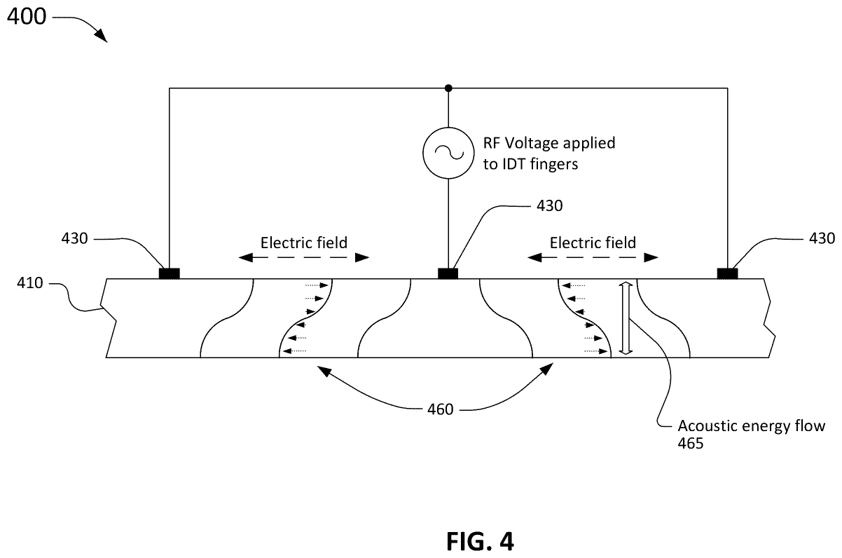

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely-excited bulk acoustic wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

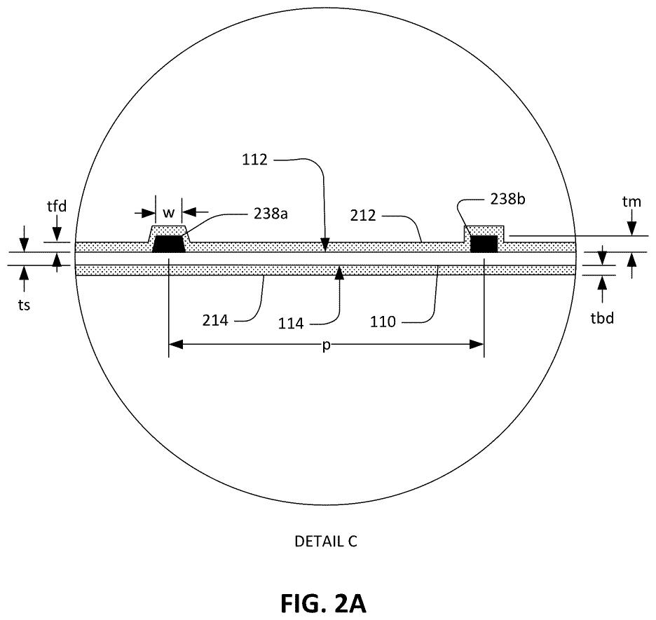

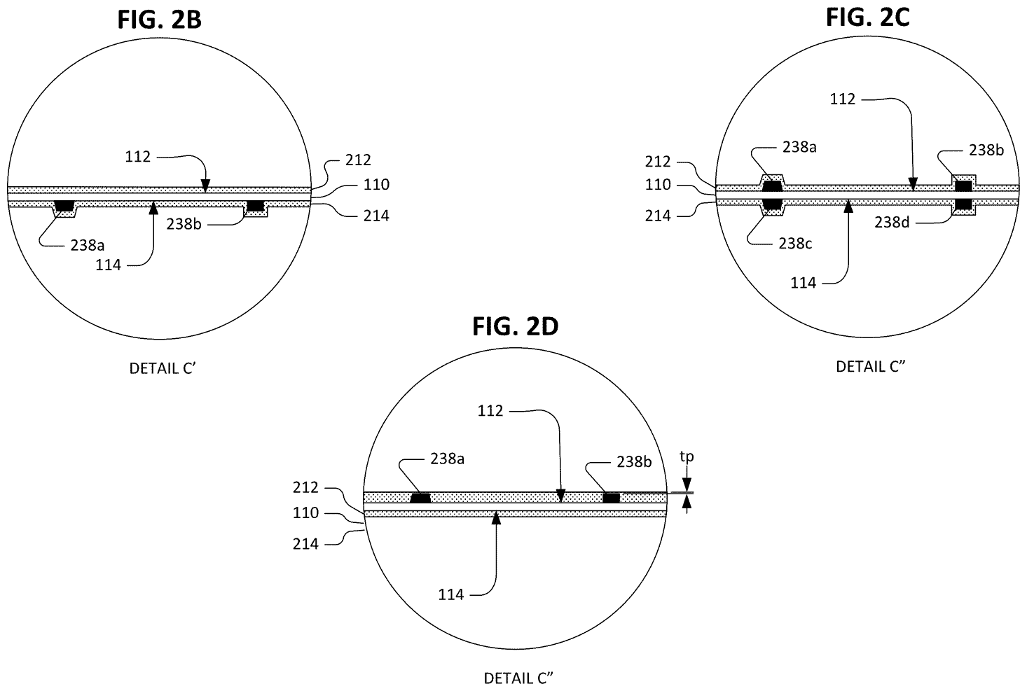

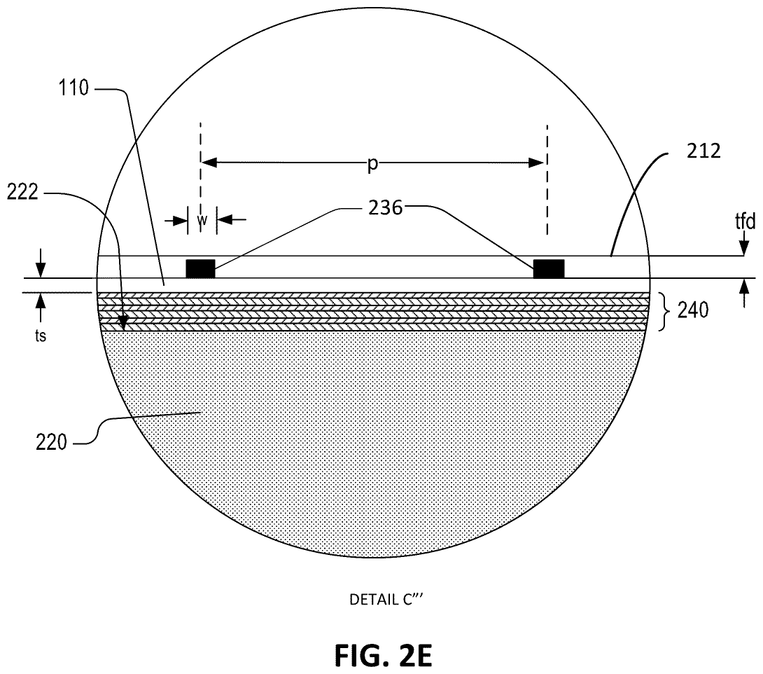

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects.

Dimension p is the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In particular, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

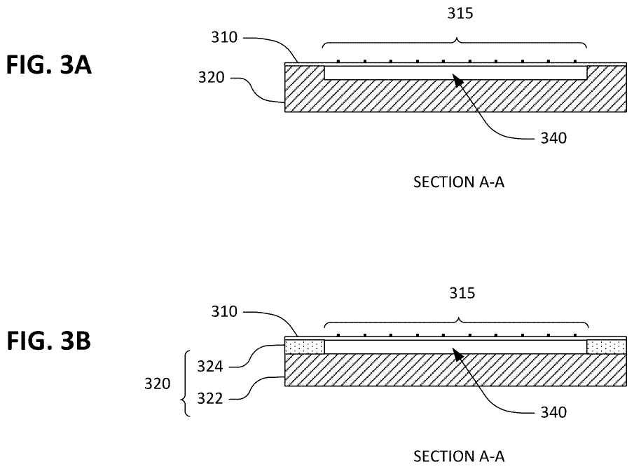

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

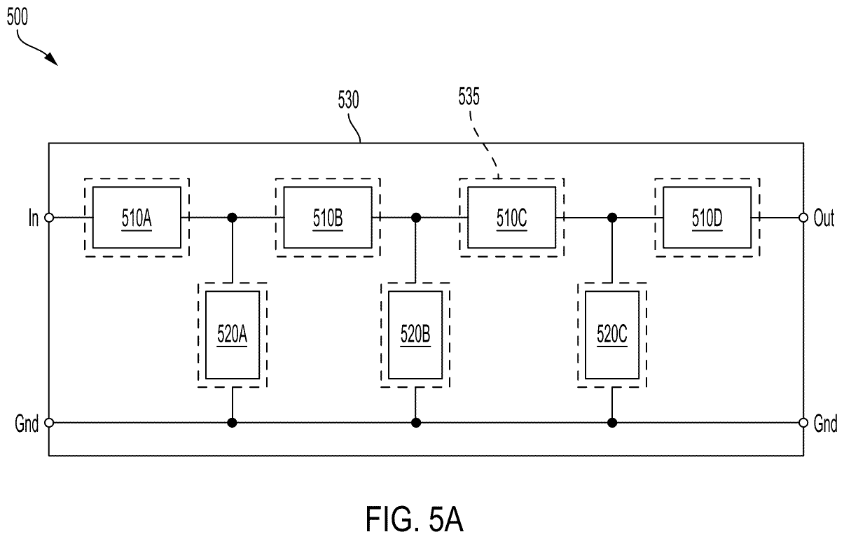

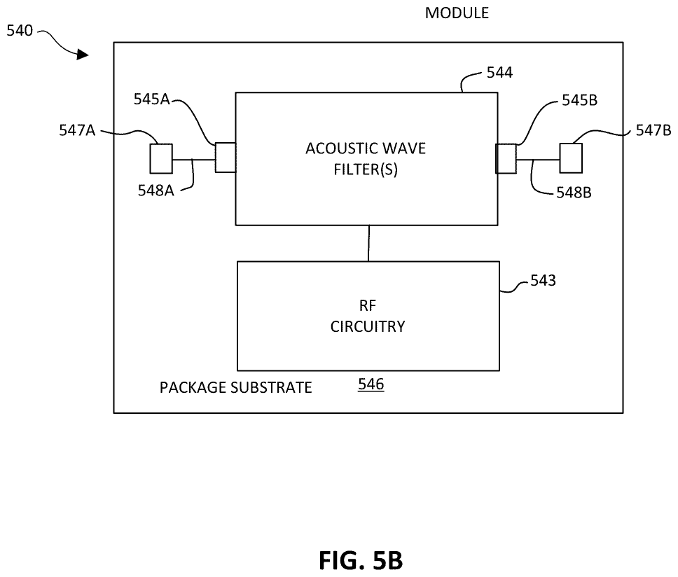

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, and 510C and the shunt resonators 520A and 520B can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

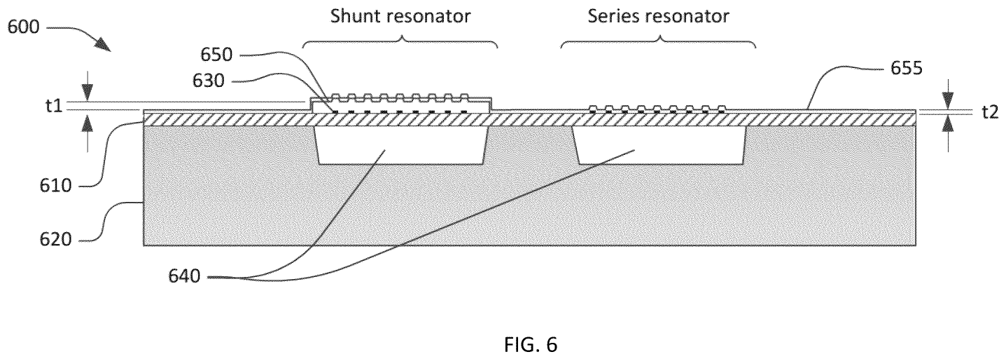

FIG. 6 is a schematic cross-sectional view of a shunt resonator and a series resonator of a filter 600 that uses a dielectric frequency setting layer to separate and/or distinguish the resonance frequencies of shunt and series resonators. A piezoelectric layer 610 is attached to a substrate 620. In an exemplary aspect, one or more dielectric layers (not shown) can be disposed between the piezoelectric layer 610 and the substrate 620. Portions of the piezoelectric layer 610 form diaphragms spanning cavities 640 in the substrate 620. Alternatively, the cavities can be disposed in the one or more dielectric layers, such as the cavity 140 in the dielectric layer 124 as described above with respect to FIG. 1B. It is also noted that in an exemplary aspect, a single piezoelectric layer 610 is shown in FIG. 6, which spans multiple cavities 640. In another exemplary aspect, a plurality of separate piezoelectric layers can each span a respective cavity 640.

In either event, interleaved IDT fingers, such as finger 630, are formed on the diaphragms. The interleaved IDT fingers 630 can correspond to fingers 136, 238a, 238b, for example. Moreover, a first dielectric layer 650, having a thickness t1, is formed over the IDT of the shunt resonator. In an exemplary aspect, the first dielectric layer 650 can be provided as considered a “frequency setting dielectric layer,” which is a layer of dielectric material applied to a first subset of the resonators in a filter to offset the resonance frequencies of the first subset of resonators with respect to the resonance frequencies of resonators that do not receive the frequency setting dielectric layer. In an exemplary aspect, the frequency setting dielectric layer may be formed using SiO₂. The frequency setting dielectric layer may also be formed using silicon dioxide, silicon nitride, aluminum oxide, aluminum nitride, beryllium oxide, tantalum oxide, tungsten oxide, or some other dielectric material. The frequency setting dielectric layer may be formed using a laminate or composite of two or more dielectric materials.

A second dielectric layer 655, having a thickness t2, may be deposited over both the shunt and series resonators. According to an exemplary aspect, the second dielectric layer 655 can be provided to seal and passivate the surface of the filter 600. The second dielectric layer may be formed using the same material as the first dielectric layer 650 or a different material. The second dielectric layer 655 may be formed using a laminate or composite of two or more different dielectric materials. Further, the thickness of the second dielectric layer 655 may be locally adjusted to fine-tune the frequency of the filter 600. Thus, the second dielectric layer 655 can be referred to as the “passivation and tuning layer.” In an example, a front-side dielectric layer may include the first dielectric layer 650 and/or the second dielectric layer 655. The front-side dielectric layer may be formed on a top side of the piezoelectric layer 610. In an example (not shown in FIG. 6), a back-side dielectric layer may be formed on a bottom side of the piezoelectric layer 610. In the example shown in FIG. 6, the top side of the piezoelectric layer 610 is further away from the cavities 640 than the bottom side of the piezoelectric layer 610. The resonance frequency of an XBAR may be approximately proportional to the inverse of the total thickness of the diaphragm including the piezoelectric layer 610 and the dielectric layers 650, 655. That is, thinner XBARs may have higher resonant frequencies than thicker XBARs that otherwise have the same configuration. Moreover, the diaphragm of the shunt resonator may be thicker than the diaphragm of the series resonator by the thickness t1 of the dielectric frequency setting layer 650. Thus, the shunt resonator will have a lower resonance frequency than the series resonator. The difference in resonance frequency between series and shunt resonators may be determined by the thickness t1.

In an exemplary aspect, XBARs may have different configurations, such as a diaphragm-based XBAR and an SM-XBAR. A diaphragm-based XBAR may include a diaphragm or a membrane, such as a portion of a piezoelectric layer, over a cavity of the diaphragm-based XBAR such as shown in FIGS. 1A and 1B. The diaphragm-based XBAR may also be referred to as a membrane-based XBAR. In an example, the diaphragm-based XBAR has a cavity above and below the diaphragm (e.g., the portion of the piezoelectric layer). The cavity may be filled with air or gas. In an example, the cavity may be devoid of gas, and a vacuum is formed in the cavity with a pressure that is below a threshold.

In an aspect, an SM-XBAR may include a portion of a piezoelectric layer that is solidly mounted over a substrate with an acoustic mirror, such as a Bragg reflector, disposed therebetween and an IDT on a surface of the piezoelectric layer, such as shown in FIG. 2E. In an example, the SM-XBAR may use an acoustic mirror, such as a Bragg reflector, on at least one side of the portion of the piezoelectric layer.

In some examples, properties of different types of XBARs may be complementary.

SM-XBARs may have good power handling capability, mechanical stability, and robustness. In some examples, SM-XBARs may have better power handling capability, mechanical stability, and robustness than diaphragm-based XBARs. In some examples, diaphragm-based XBARs may have higher Q factors and higher electromechanical coupling (k2) than SM-XBARs. In an example, manufacturing diaphragm-based XBARs may be lower cost than manufacturing SM-XBARs.

In some examples, filters using only a single type of XBARs, such as only diaphragm-based XBARs or only SM-XBARs, may not benefit from other types of XBARs. According to an aspect, a filter that uses or combines multiple types of XBARs, such as two types of XBARs including diaphragm-based XBAR(s) and SM-XBAR(s) may take advantage of properties of the multiple types of XBARs. A filter that uses or combines multiple types of XBARs can be referred to as a hybrid filter. For example, a hybrid filter that combines diaphragm-based XBAR(s) and SM-XBAR(s) may have combined benefits of diaphragm-based XBAR(s) and SM-XBAR(s), such as higher coupling k2 and lower loss than a filter including only SM-XBAR(s), better power handing and mechanical stability than a filter including only diaphragm-based XBAR(s).

Using a hybrid filter including, for example, diaphragm-based XBAR(s) and SM-XBAR(s) may improve performance of a filter, such as an n79 filter associated with an n79 band. In an example, the n79 filter may uses a frequency range from 4400 MHz to 5000 MHz. Examples described in the application use the n79 filter, however, a hybrid filter may be applied to any suitable RF filters with various operating frequencies, and the descriptions can be suitably adapted.

In the descriptions below, a hybrid filter refers to a filter that combines at least one diaphragm-based XBAR and at least one SM-XBAR.

The insertion loss (IL) of a filter may indicate how much the filter affects (e.g., attenuates) a signal at a given frequency. In some examples, diaphragm-based XBARs have higher quality factors (Q factors) than Q factors of SM-XBARs, which may yield a better filter IL for the hybrid filter than a filter including only the SM-XBARs. In an aspect, a hybrid filter that combines diaphragm-based XBAR(s) and SM-XBAR(s) may improve a filter IL, such as reducing the filter IL.

In an example, the hybrid filter has a filter architecture similar to that shown in FIG. 5A. At least one series resonator in the hybrid filter is a diaphragm-based XBAR.

In an aspect, one or more matching components (also interchangeably referred to as matching elements), such as matching inductor(s) that are positioned at an input port and/or an output port of a filter that includes only SM-XBARs may be eliminated when at least one of the SM-XBARs in the filter is replaced by diaphragm-based XBAR(s), and thus resulting in a hybrid filter having a smaller product size (e.g., a smaller filter size) and a better IL when the external matching inductors are not used.

In an example, at least one shunt resonator in the hybrid filter is a diaphragm-based XBAR. In an example, two shunt resonators at an input port and an output port in the hybrid filter are diaphragm-based XBARs.

In an example, at least one SM-XBAR and at least one diaphragm-based XBAR in the hybrid filter are positioned on a single chip. In an example, at least one SM-XBAR and at least one diaphragm-based XBAR in the hybrid filter XBAR are positioned on multiple chips.

In an example, SM-XBAR(s) and diaphragm-based XBAR(s) may have different cuts of piezoelectric lithium niobate or lithium tantalate such as rotated Z-cut, Z-cut, rotated YX cut, Y-cut, and the like, for example, when the SM-XBAR(s) and the diaphragm-based XBAR(s) in the hybrid filter are positioned on multiple chips.

In an example, SM-XBAR(s) in the hybrid filter are positioned on a first chip, and diaphragm-based XBAR(s) in the hybrid filter are positioned in a second chip that is different from the first chip.

In an example, series resonators in the hybrid filter are positioned on a third chip, and shunt resonators in the hybrid filter are positioned in a fourth chip that is different from the third chip.

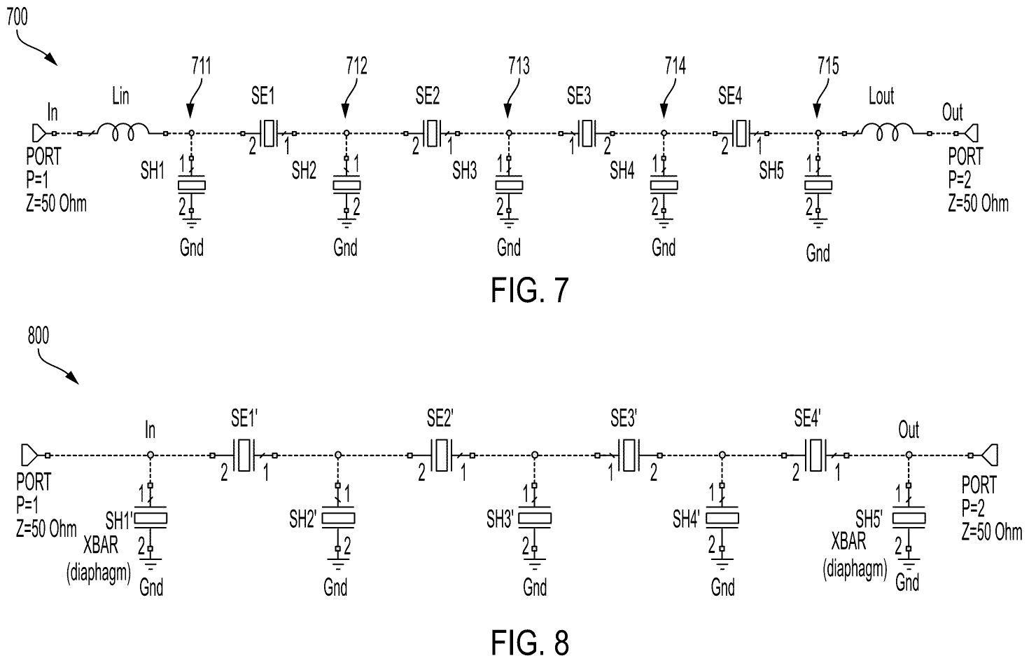

FIG. 7 shows an example of a filter 700 including only SM-XBARs according to an aspect of the disclosure. The filter 700 may be a high frequency bandpass filter, such as an n79 filter. The filter 700 has a ladder filter architecture. In an example, the filter 700 may include a split-ladder filter architecture where the filter 700 is split between multiple chips. In an example, the SM-XBARs in the filter 700 are on a single chip. The circuit diagram and layout of the filter 700 may be similar to those of the filter 500 described in FIG. 5A. In the example shown in FIG. 7, the filter 700 may include an inductor Lin, four series resonators SE1 to SE4, an inductor Lout, and five shunt resonators SH1-SH5, and the architecture may be referred to as a 4s5p configuration. In an example, the inductors Lin and Lout are used for impedance matching and may be referred to as matching inductors. The inductor Lin, the series resonators SE1 to SE4, and the inductor Lout are connected in series between a first port (e.g., “In”) and a second port (e.g., “Out”). Similar to that described in FIG. 5A, the filter 700 may be bidirectional and either port (“In” or “Out”) may serve as the input port or output port of the filter 700. A node 711 is between the inductor Lin and the series resonator SE1. Nodes 712, 713 and 714 are between the series resonators SE1-SE4. A node 715 is between the inductor Lout and the series resonator SE4.

The five shunt resonators SH1-SH5 are connected from the nodes 711-715 to a ground or a ground connection (“Gnd”), respectively. In FIG. 7, all the shunt resonators and series resonators are SM-XBARs such as shown in FIG. 2E. The inclusion of four series and five shunt resonators is an example. In each of the exemplary filter configurations described herein, connection points or nodes “1” and “2” are shown in FIGS. 7-12 and 15, which can represent the electrical potentials and/or opposing busbars according to various exemplary aspects. Moreover, it is noted that a filter may have more or fewer than 9 total resonators, more or fewer than 4 series resonators, and more or fewer than 5 shunt resonators. Table 1 shows examples of resonance frequencies (Fr) of the resonators SE1-SE4 and SH1-SH5, respectively.

TABLE 1
Resonance frequencies (Fr) of the
resonators SE1-SE4 and SH1-SH5.

| Resonators | Fr [MHz] |
|---|---|
| SE1 | 4764 |
| SE2 | 4683 |
| SE3 | 4579 |
| SE4 | 4740 |
| SH1 | 4103 |
| SH2 | 4174 |
| SH3 | 4181 |
| SH4 | 4040 |
| SH5 | 4093 |

As described above, the performance of the filter 700 may be improved by including another type of XBAR, such as diaphragm-based XBAR(s). In an example, at least one SM-XBAR in the filter 700 may be replaced by diaphragm-based XBAR(s) to form a hybrid filter, such as hybrid filters 800, 900, 1000, 1100, and 1200 in FIGS. 8-12, respectively.

In an aspect, each of the hybrid filters 800, 900, 1000, 1100, and 1200 include both diaphragm-based XBAR(s) and SM-XBAR(s) in the filter 700. The hybrid filters 800, 900, 1000, 1100, and 1200 may have an improved IL, such as a smaller IL, than the filter 700 that includes only SM-XBAR(s). In an example, the hybrid filters 800, 900, 1000, 1100, and 1200 are n79 filters with improved performance than that of the filter 700, and the improved performance may include benefits provided by both SM-XBAR(s) and diaphragm-based XBAR(s).

In an example, an equivalent circuit corresponding to each of the filters 700, 800, 900, 1000, 1100, and 1200 may be modeled using a Butterworth-van Dyke (BVD) model. The descriptions may be suitably adapted if other models are used, and the properties or characteristics of filters 700, 800, 900, 1000, 1100, and 1200 are similar regardless of the models used.

FIGS. 8-12 show examples of the hybrid filters 800, 900, 1000, 1100, and 1200, respectively according to aspects of the disclosure. In the examples shown in FIGS. 8-12, the hybrid filters 800, 900, 1000, 1100, and 1200 have a similar filter architecture as that of the filter 700, for example, each of the hybrid filters 800, 900, 1000, 1100, and 1200 has four series resonators and five shunt resonators, and thus has a 4s5p configuration/architecture. As described above in FIGS. 5A and 7, each of the hybrid filters 800, 900, 1000, 1100, and 1200 may include more or less series resonators, more or less shunt resonators, and/or more or less total number of resonators.

As described below, in some examples, the hybrid filters 800, 900, 1000, and 1100 do not include matching inductors.

The hybrid filters 800 and 900 are similar, and may be referred to as first hybrid filters 800 and 900. In an exemplary aspect, the higher Q factor and the higher electromechanical coupling k2 of XBAR(s) may be used to obtain an improved IL in an n79 filter such as the first hybrid filters 800 and 900. The hybrid filter 800 includes four series resonators SE1′ to SE4′ and five shunt resonators SH1′ to SH5′. In the example shown in FIG. 8, the four series resonators SE1′ to SE4′ and the shunt resonators SH2′ to SH4′ are SM-XBARs. The shunt resonators SH1′ and SH5′ are diaphragmed-based XBARs. In the hybrid filter 800, the XBARs are connected between (i) the input port (e.g., “IN”) and the output port (e.g., “OUT”) of the hybrid filter 800 and (ii) the ground (“Gnd”) of the hybrid filter 800. As described in FIG. 7, either port (“IN” or “OUT”) may serve as the input or output of the hybrid filter 800. In an example, the series resonators SE1′ to SE4′ in FIG. 8 are similar or identical to SE1 to SE4 in FIG. 7, respectively, and are coupled in series between the input port IN and the output port OUT. In an example, the shunt resonators SH2′ to SH4′ in FIG. 8 are similar or identical to SH2 to SH4 in FIG. 7, respectively.

Comparing the filters 700 and 800, the hybrid filter 800 includes diaphragm-based XBARs, such as the shunt resonators SH1′ and SH5′. As shown, shunt resonator SH1′ is connected between (i) a node directly between the first series acoustic resonator SE1′ of the plurality of shunt acoustic resonators and the input port IN, and (ii) a ground of the bandpass filter. Similarly, shunt resonator SH5′ is connected between (i) a node directly between the last series acoustic resonator SE4′ of the plurality of shunt acoustic resonators and the output port OUT, and (ii) the ground of the bandpass filter.

In an aspect, the resonator coupling difference between SM-XBARs and diaphragm-based XBARs may be used to eliminate matching element(s) (e.g., Lin and/or Lout in FIG. 7) in a ladder filter. For example, diaphragm-based XBARs such as SH1′ and SH5′ have larger k2 than the SM-XBARs in the filter 700. Thus, when SH1 and SH5 are replaced by SH1′ and SH5′, respectively, Lin and Lout may be eliminated as shown in FIG. 8. When matching elements (e.g., Lin and Lout in FIG. 7) are removed, a size of a hybrid filter may be reduced. For example, a size of the hybrid filter 800 is smaller than a size of the filter 700. As the matching elements (e.g., Lin and Lout) may be lossy, the hybrid filter 800 without the lossy Lin and Lout may have a smaller loss (e.g., a smaller IL) than that of the filter 700.

In exemplary aspects, the hybrid filters 800, 900, 1000, 1100, and 1200 can be split-ladder filter architectures where the filters 800, 900, 1000, 1100, and 1200 are split between multiple chips. For example, in an exemplary aspect, each of the hybrid filters 800, 900, 1000, 1100, and 1200 can comprise a plurality of bulk acoustic wave resonators that include a first subset of bulk acoustic wave resonators and a second subset of bulk acoustic wave resonators. Using multiple chips, the filter can be implemented with a first chip comprising the first subset of bulk acoustic wave resonators, and a second chip comprising the second subset of bulk acoustic wave resonators. Moreover, a circuit card can be provided that is coupled to the first chip and the second chip. The circuit card can include one or more electrical connections between the first subset of bulk acoustic wave resonators of the first chip and the second subset of bulk acoustic wave resonators of the second chip to form the split-ladder filter architecture.

Using multiple chips enables the filter circuits to be manufactured using different steps and process flows to maximize efficiency of the process and/or the physical layout of the filter. For example, in one aspect, the first subset of bulk acoustic wave resonators of the first chip can include the plurality of series acoustic resonators, and the second subset of bulk acoustic wave resonators of the second chip can include the plurality of shunt acoustic resonators. Moreover, in this aspect, the first subset of bulk acoustic wave resonators can have a stack thickness that is smaller than a stack thickness of the second subset of bulk acoustic wave resonators. It should be appreciated that varying the stack thickness (or stack height) enables the circuit design to adjust and tune the frequency of each acoustic resonator. In general, the stack can be considered all of the layers that make up the resonator in the vertical or thickness direction according to an exemplary aspect. Moreover, the stack thickness can be adjusted by varying one or more of dielectric thickness, piezoelectric thickness, different dies/substrates, or any combination thereof.

In another exemplary aspect, the first subset of bulk acoustic wave resonators of the first chip includes the at least one SM-XBAR, and the second subset of bulk acoustic wave resonators of the second chip includes the at least one XBAR. That is, in this aspect, the first chip may include all the SM-XBARs of the ladder filter circuit while the second chip may include all of the XBARs of ladder filter circuit. Such a design would enable the manufacturer, for example, to form the Bragg stack (or Bragg reflector) on only the first chip and avoid this process steps for the second chip.

In another exemplary aspect, the hybrid filters 800, 900, 1000, 1100, and 1200 can be split-ladder filter architectures where some or all of the plurality of series acoustic resonators and the plurality of shunt acoustic resonators are all disposed on a single chip. In this exemplary aspect, at least a portion (e.g., one or more) of the plurality of series acoustic resonators can have a stack thickness that is smaller than a stack thickness of at least a portion of the plurality of shunt acoustic resonators. For example, to tune the resonant frequency, the piezoelectric layer of one or more of the XBARs (e.g., one or more of the shunt resonators) can be thicker than a thickness of a piezoelectric layer of one or more of the SM-XBARs (e.g., one or more of the series resonators). Moreover, to manufacturer the single chip to have both the XBARs and the SM-XBARs, the Bragg reflector(s) of the one or more SM-XBAR can extend across the single chip in a planar direction (e.g., deposited thereon during manufacture), but then the Bragg reflector(s) can include an etched region to form the cavity of the each of the XBARs of the ladder filter circuit.

According to these various configurations, using hybrid XBARs on one or more chips enables the overall size of the filter to be reduced according to the design specifications.

Table 2 compares characteristics of the SM-XBARs (e.g., SE1′ to SE4′ and SH2′ to SH4′) and the diaphragm-based XBARs (e.g., SH1′ and SH5′) in the hybrid filter 800. The characteristics may include BVD model parameters a coupling parameter gamma (T), a Q-factor of the motional resonance (Qm), a Q-factor of the static capacitance (QC0), and/or the like. In an aspect, the coupling parameter gamma (T) may be a metric defined by the following equation.

$$Γ = \frac{1}{{( Fa / Fr )}^{2} - 1}$$

where Fa is the antiresonance frequency and Fr is the resonance frequency. Large values for gamma may correspond to smaller separation between the resonance and anti-resonance frequencies. Low values of gamma may indicate strong coupling which may be good for design of wideband ladder filters.

TABLE 2
Characteristics (gamma, Qm, and QC0) of the SM-XBARs (e.g.,
SE1′ to SE4′ and SH2′ to SH4′) and the
diaphragm-based XBARs (e.g., SH1′ and SH5′) in the hybrid filter 800.

| Technology | Gamma | Qm (motional) | QC0 (static) |
|---|---|---|---|
| SM-XBAR | 4 | 500 | 200 |
| Diaphragm-based XBAR | 2.3 | 1000 | 400 |

Table 2 illustrates that, in some examples, the Q factors (e.g., Qm and QC0) of the SM-XBARs are smaller than the Q factors of the diaphragm-based XBARs in the hybrid filter 800.

FIG. 8 shows an example where both matching elements Lin and Lout in the filter 700 are eliminated. In some examples (not shown in FIG. 8), only one of SH1′ and SH5′ is a diaphragm-based XBAR, and another one of SH1′ and SH5′ may be an SM-XBAR. Thus, one of Lin and Lout may be included in the hybrid filter 800 (not shown). For example, SH1′ is a diaphragm-based XBAR, and SH5′ is an SM-XBAR, and thus the hybrid filter 800 may include Lout at the second port (e.g., “Out”) and does not include Lin.

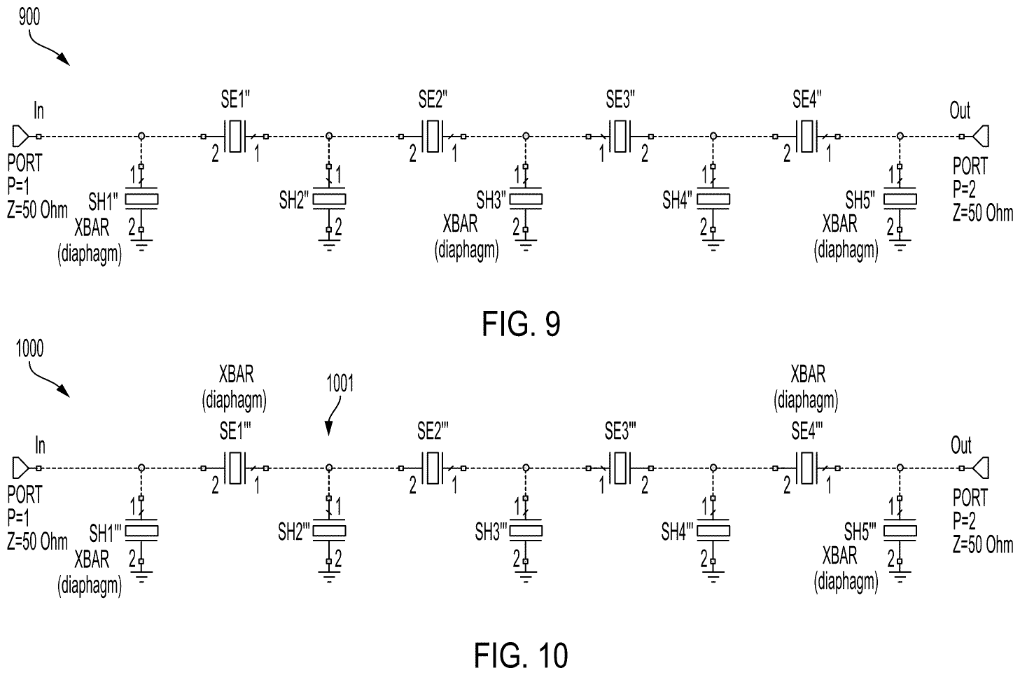

In another example, additional resonator(s) are diaphragm-based XBARs such as shown in FIGS. 9-11.

Referring to FIG. 9, the hybrid filter 900 may include four series resonators SE1″ to SE4″ and five shunt resonators SH1″ to SH5″. The resonators SH1″, SH3″, and SH5″ are diaphragm-based XBARs, and remaining resonators in the hybrid filter 900 are SM-XBARs. The hybrid filter 900 is similar to the hybrid filter 800 except that SH3″ in the hybrid filter 900 is a diaphragm-based XBAR. Table 3 shows examples of resonance frequencies of the resonators SE1″-SE4″ and SH1″-SH5″.

TABLE 3
Resonance frequencies of the resonators SE1″-SE4″
and SH1″-SH5″.

| Resonators | Fr [MHz] |
|---|---|
| SE1″ | 4777 |
| SE2″ | 4682 |
| SE3″ | 4570 |
| SE4″ | 4779 |
| SH1″ | 4172 |
| SH2″ | 4167 |
| SH3″ | 3863 |
| SH4″ | 4162 |
| SH5″ | 4120 |

The hybrid filter 900 also eliminates the matching elements Lin and Lout, may have an improved IL (e.g., a less IL) than that of the filter 700, and may have a smaller size than that of the filter 700, similarly to that described in FIG. 8.

Characteristics (e.g., gamma (T), Qm, QC0) of the SM-XBARs (e.g., SE1″ to SE4″, SH2″, and SH4″) in the hybrid filter 900 may be identical to the characteristics (e.g., gamma (I), Qm, QC0) of the SM-XBARs in the hybrid filter 800. Characteristics (e.g., gamma (T), Qm, QC0) of the diaphragm-based XBARs (e.g., SH1″, SH3″, and SH5″) in the hybrid filter 900 may be similar to the characteristics (e.g., gamma (T), Qm, QC0) of the diaphragm-based XBARs in the hybrid filter 800. The characteristics of the SM-XBARs and the diaphragm-based XBARs in the hybrid filter 900 may also be described by Table 2.

In an aspect, in addition to including diaphragm-based XBAR(s) in the shunt resonators in a filter such as shown in FIGS. 8-9, diaphragm-based XBAR(s) may be included in series resonators in a hybrid filter, as shown in FIGS. 10-12. FIG. 10 shows an example of the hybrid filter 1000 according to an aspect of the disclosure. The hybrid filter 1000 includes series resonators SE1′″ to SE4′″ and shunt resonators SH1′″ to SH5′″. The resonators SE1′″, SE4′″, SH1′″, and SH5′″ are diaphragm-based XBARs. The resonators SE2′″, SE3′″, and SH2′″ to SH4′″ are SM-XBARs. The hybrid filter 1000 may be adapted from the hybrid filter 800. For example, the hybrid filter 1000 may be similar to the hybrid filter 800 except that SE1′″ and SE4′″ in the hybrid filter 1000 are diaphragm-based XBARs.

The hybrid filter 1000 may be referred to as a second hybrid filter. In an example, the higher coupling k2 of diaphragm-based XBARs over SM-XBARs may be used in the second hybrid filter 1000. The external matching inductors such as Lin and Lout at the input and output ports of an n79 filter (e.g., the filter 700) may be eliminated by using diaphragm-based XBARs in the shunt positions, such as SH1′″ and SH5′″, and thus leading to a smaller filter size and an improved filter IL for the second hybrid filter 1000.

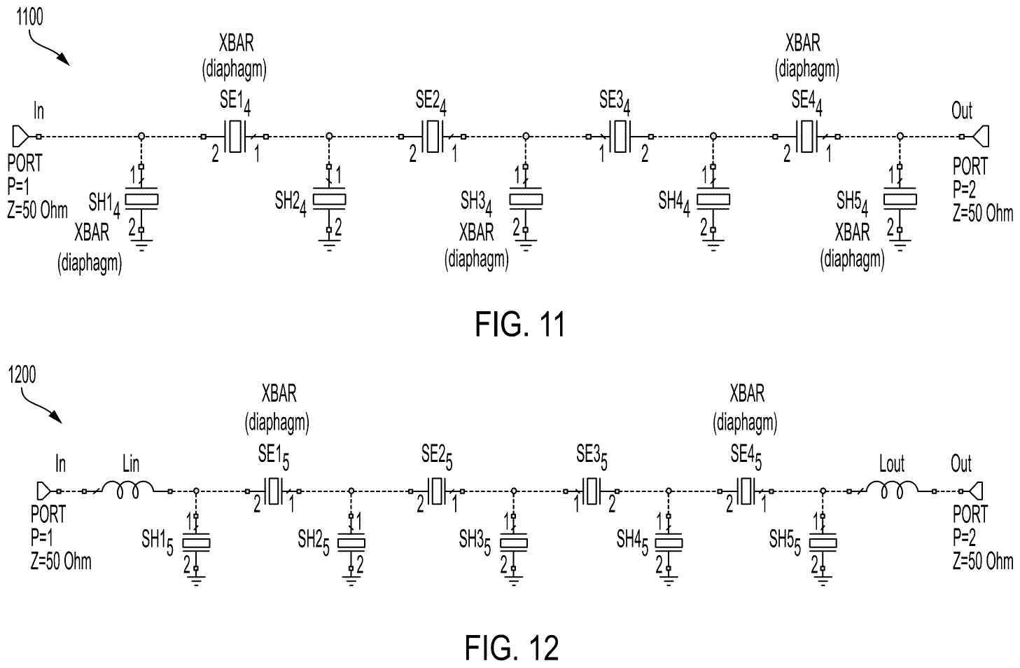

In an example, the SH3′″ (an SM-XBAR) in the hybrid filter 1000 may be replaced by a diaphragm-based XBAR SH3₄, and thus forming the hybrid filter 1100. The hybrid filter 1100 may also be referred to as a second hybrid filter. FIG. 11 shows an example of the hybrid filter 1100 according to an aspect of the disclosure. The hybrid filter 1100 includes series resonators SE1₄ to SE4₄ and shunt resonators SH1₄ to SH5₄. The resonators SE1₄, SE4₄, SH1₄, SH3₄, and SH5₄ are diaphragm-based XBARs. The resonators SE2₄, SE3₄, SH2₄, and SH4₄ are SM-XBARs. The hybrid filter 1100 does not include the matching elements such as Lin and Lout in FIG. 7. The hybrid filter 1100 may be similar to the hybrid filter 1000 except that the SH3′″ (an SM-XBAR) in the hybrid filter 1000 is replaced by the diaphragm-based XBAR SH3₄ in the hybrid filter 1100.

Comparing FIGS. 9 and 11, the hybrid filter 1100 may be adapted from the hybrid filter 900, for example, SE1″ and SE4″ in the hybrid filter 900 are replaced by the diaphragm-based XBARs SE1₄ and SE4₄.

Table 4 shows examples of resonance frequencies of the resonators SE14-SE44 and SH14-SH54 used in the hybrid filter 1100.

TABLE 4
Resonance frequencies of the resonators
SE1₄-SE4₄ and SH1₄-SH5₄.

| Resonators | Fr [MHz] |
|---|---|
| SE1₄ | 4705 |
| SE2₄ | 4650 |
| SE3₄ | 4572 |
| SE4₄ | 4690 |
| SH1₄ | 4236 |
| SH2₄ | 4135 |
| SH3₄ | 3790 |
| SH4₄ | 4131 |
| SH5₄ | 4016 |

In an example, the characteristics (gamma, Qm, and QC0) of the SM-XBARs and the diaphragm-based XBARs in the hybrid filters 1000 and 1100 are described by Table 2. In the example described by Table 2, Q factors of the SM-XBARs in the hybrid filters 1000 and 1100 may be smaller than Q factors of the diaphragm-based XBARs in the hybrid filters 1000 and 1100.

According to an exemplary aspect, removing the matching inductors from the hybrid filters 1000 and 1100 may be based on the coupling k2 of diaphragm-based XBARs being higher than that of SM-XBARs, and may not require assumptions regarding the Q factors of the diaphragm-based XBARs. For example, Q factors of the SM-XBARs in the hybrid filters 1000 and 1100 may be similar or identical to Q factors of the diaphragm-based XBARs in the hybrid filters 1000 and 1100, and the matching inductors may be removed from the hybrid filters 1000 and 1100 as the coupling k2 of diaphragm-based XBARs are higher than that of SM-XBARs.

In FIGS. 8-11, the shunt resonators in the hybrid filters 800, 900, 1000, and 1100 include diaphragm-based XBARs. In some examples, shunt resonators in a hybrid filter do not include diaphragm-based XBARs, and series resonators in the hybrid filter may include at least one diaphragm-based XBAR, such as shown in FIG. 12. FIG. 12 shows an example of the hybrid filter 1200 according to an aspect of the disclosure. The hybrid filter 1200 includes series resonators SE1₅ to SE4₅ and shunt resonators SH1₅ to SH5₅. At least one of the resonators SE1₅ and SE4₅ may be diaphragm-based XBAR(s), and remaining resonators in the hybrid filter 1200 are SM-XBARs. The hybrid filter 1200 may or may not include matching elements such as Lin and Lout. In the example shown in FIG. 12, the resonators SE1₅ and SE4₅ are diaphragm-based XBARs, and the hybrid filter 1200 includes Lin and Lout.

In the example of FIG. 12, each of the diaphragm-based XBARs SE1₅ to SE4₅ is connected to the input port or the output port of the hybrid filter 1200. In some examples (not shown), a diaphragm-based XBAR that is a series resonator (e.g., the SE2₅) may be connected between two nodes that are different from the first port and the second port of the hybrid filter 1200. Positions (e.g., connected to the input port, the output port, or a node that is different from the input and output nodes) of series resonator(s) that are diaphragm-based XBAR(s) may depend on specifications for a hybrid filter.

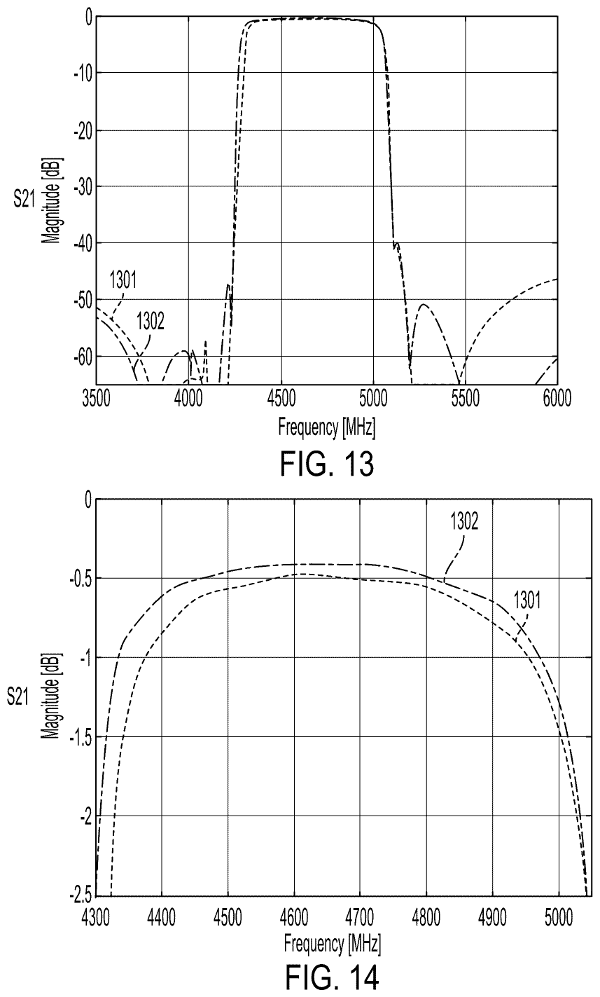

Referring to FIG. 9, in some examples, if additional SM-XBARs in the hybrid filter 900 are to be replaced with diaphragm-based XBARs, replacing additional SM-XBARs in the series resonators may have more influence in a passband of the hybrid filter 900 than replacing additional SM-XBARs in the shunt resonators. Referring to FIGS. 9 and 11, additional SM-XBARs in the series resonators such as SE1″ and SE4″ may be replaced by SE1₄ and SE4₄ (diaphragm-based XBARs) to form the hybrid filter 1100. The influence of such replacement is indicated by FIGS. 13-14.

Filters, such as the hybrid filters 900 and 1100, may be characterized by various parameters including scattering parameters (S-parameters, also referred to as elements of a scattering matrix or S-matrix). An element of the S-matrix is a forward voltage gain S21. S21 may indicate an input-output transfer function between two ports of a filter. FIGS. 13-14 show a comparison between two performances (e.g., simulated performances) of the first hybrid filter 900 and the second hybrid filter 1100 according to an aspect of the disclosure. Plots 1301 and 1302 may indicate forward voltage gains (S21) of the first hybrid filter 900 and the second hybrid filter 1100, respectively. FIG. 13 shows the plots 1301 and 1302 in a frequency range from 3500 MHZ to 6000 MHz that include resonant frequencies of the first hybrid filter 900 and the second hybrid filter 1100. FIG. 14 shows the plots 1301 and 1302 in a frequency range from 4300 MHz to approximately 5050 MHz which may correspond to the n79 band.

FIGS. 13-14 show an improved IL near the resonant frequencies of the first hybrid filter 900 and the second hybrid filter 1100 as a number of diaphragm-based XBARs increases by 2 from the first hybrid filter 900 to the second hybrid filter 1100. More specifically, Table 5 shows IL differences (ΔIL in a unit of dB) at three difference frequencies, such as a lower band edge (LBE), a middle band (MB), and an upper band edge (UBE). In the example shown in FIGS. 13-14 and Table 5, the LBE is 4400 MHZ, the MB is 4700 MHZ, and the UBE is 5000 MHz. Table 5 indicates an IL improvement of 0.17 dB at the UBE when the number of diaphragm-based XBARs increases by 2 from the first hybrid filter 900 to the second hybrid filter 1100.

TABLE 5
ΔIL at difference frequencies

| LBE (4400 MHz) [dB] | MB (4700 MHz) [dB] | UBE (5000 MHz) [dB] |
|---|---|---|
| 0.24 | 0.1 | 0.17 |

As described above, adding diaphragm-based XBARs to a filter (e.g., the filer 700) that uses an SM-XBAR design allows matching inductors (e.g., Lin and Lout in FIG. 7) to be eliminated.

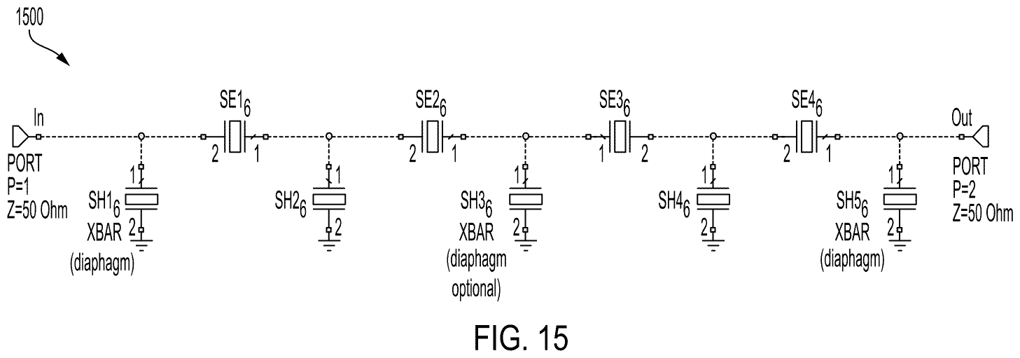

In an exemplary aspect, the resonance coupling difference between an SM-XBAR and a diaphragm-based XBAR may be used to eliminate matching elements such as matching inductors in a ladder filter, such as a hybrid filter 1500 in FIG. 15. FIG. 15 shows an example of the hybrid filter 1500. In an example, Q factors of SM-XBARs in the hybrid filter 1500 are identical to Q factors of diaphragm-based XBARs in the hybrid filter 1500. The difference between the SM-XBARs and the diaphragm-based XBARs in the hybrid filter 1500 is the coupling k2.

In an example, SH1 and SH5 and optionally SH3 in the filter 700 may be replaced by diaphragm-based XBARs, such as shown in FIG. 15. The hybrid filter 1500 includes series resonators SE1₆ to SE4₆ and shunt resonators SH1₆ to SH5₆. The resonators SH1₆ and SH5₆ and optional SH36 are diaphragm-based XBARs. Remaining resonators in the hybrid filter 1500 are SM-XBARs. The hybrid filter 1500 does not include the matching elements such as Lin and Lout in FIG. 7. Resonance frequencies of SE1₆ to SE4₆ and SH16 to SH56 are shown in Table 3. In this case, the characteristics of the SM-XBARs and the diaphragm-based XBARs in the hybrid filter 1500, such as gamma, Qm, and QC0 are shown in Table 5.

TABLE 5
Characteristics (gamma, Qm, and QC0) of the SM-XBARs and
the diaphragm based XBARs in the hybrid filter 1500.

| Technology | Gamma | Qm (motional) | QC0 (static) |
|---|---|---|---|
| SM-XBAR | 4 | 500 | 200 |
| XBAR | 2.3 | 500 | 200 |

As shown in Table 5, the Q factors of the SM-XBARs in the hybrid filter 1500 are identical to the Q factors of the diaphragm based XBARs in the hybrid filter 1500. The difference between the SM-XBARs and the diaphragm-based XBARs in the hybrid filter 1500 is the coupling k2 (which is related to the gamma parameter Γ). When the shunt resonators (e.g., SH1₆ to SH5₆) are diaphragm-based XBARs, lossy matching inductors may be eliminated which may improve IL and reduce the filter size.

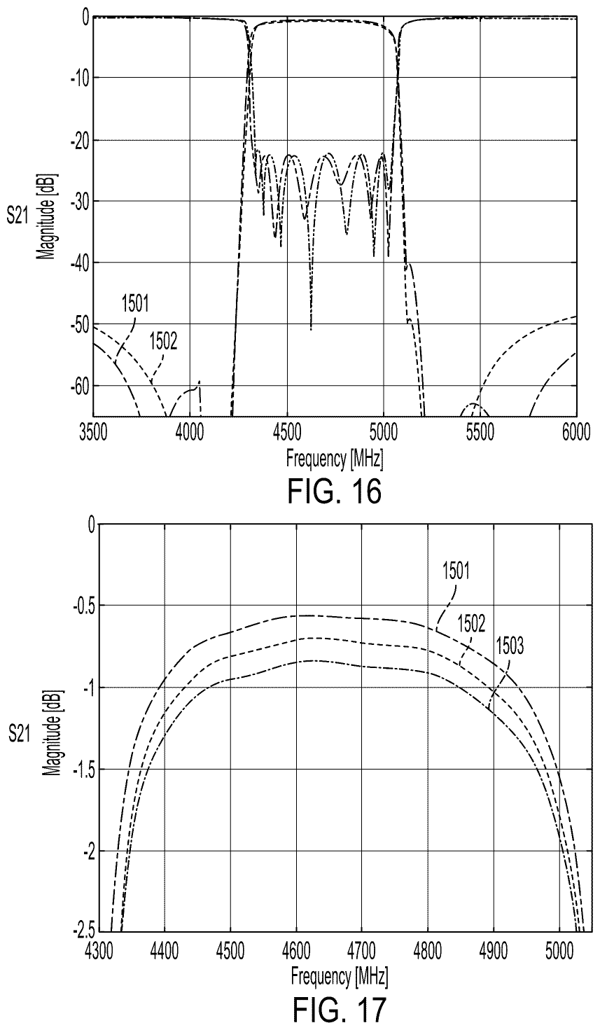

FIGS. 16-17 show a comparison between multiple simulated performances of the hybrid filter 1500 and a filter that uses only SM-XBARs (such as the filter 700) according to an aspect of the disclosure. Plots 1501 and 1502 in FIGS. 16-17 may indicate forward voltage gains (S21, or Insertion Loss (IL)) of the hybrid filter 1500 and the filter 700, respectively. FIG. 16 shows the plots 1501 and 1502 between a frequency range from 3500 MHz to 6000 MHz. FIG. 17 shows the plots 1501 and 1502 near the resonant frequencies of the hybrid filter 1500 and the filter 700, such as between the frequency range from 4300 MHz to approximately 5050 MHz.

The filter 700 may include surface mount inductors (also interchangeably referred to as SMD inductors), inductors integrated into a PCB (also interchangeably referred to as PCB inductors), and/or the like. In the example shown in FIG. 17, performances of the filter 700 including the SMD inductors and the filter 700 including the PCB inductors are indicated by the plot 1502 and a plot 1503, respectively. The plot 1503 indicates a forward voltage gain (S21) of the filter 700 including the PCB inductors and having a QL of 20. In contrast, the QL of the plot 1502 is 50.

FIGS. 16-17 show an improved IL near the resonant frequencies of the hybrid filter 1500 by including diaphragm-based XBARs. In an example, the inductors such as the SMD inductors or the PCB inductors are eliminated from the hybrid filter 1500. More specifically, Table 6 shows IL differences (ΔIL in a unit of dB) at three difference frequencies, such as the LBE (4400 MHz), the MB (4700 MHZ), and the UBE (5000 MHz), between the hybrid filter 1500 and the filter 700 having two different inductors. The first row of Table 6 shows ΔIL between the hybrid filter 1500 and the filter 700 having the PCB inductors (QL being 20). The second row of Table 6 shows ΔIL between the hybrid filter 1500 and the filter 700 having the SMD inductors (QL being 50). Table 6 indicates that the UBE IL may be improved by more than 0.3 dB.

TABLE 6
ΔIL at difference frequencies

| SM-XBAR Filter QL | LBE [dB] | MB [dB] | UBE [dB] |
|---|---|---|---|
| 20 | 0.34 | 0.29 | 0.36 |
| 50 | 0.21 | 0.15 | 0.32 |

In an exemplary aspect, the improved IL may result from both the coupling k2 difference and the Q factor difference between SM-XBARs and diaphragm-based XBARs, such as described in FIGS. 8-9. Resonator coupling k2 difference between SM-XBARs and diaphragm-based XBARs may be used to eliminate matching elements in a ladder filter, which may result in a reduced loss (e.g., a reduced IL) and a reduced filter size. In an example, larger Q factors from diaphragm-based XBARs may be used to improve IL in a hybrid filter including both diaphragm-based XBARs and SM-XBARs.

In view of the foregoing, a bandpass filter such as a hybrid bandpass filter may be implemented using various configurations. In particular, the bandpass filter, such as the hybrid bandpass filter (e.g., the hybrid filter 800, 900, 1000, 1100, or 1500), may include a plurality of series acoustic resonators and a plurality of shunt acoustic resonators. The plurality of shunt acoustic resonators includes a first XBAR (e.g., a first one of SH1′ and SH5′ in the hybrid filter 800, a first one of SH1″ and SH5″ in the hybrid filter 900, a first one of SH1′″ and SH5′″ in the hybrid filter 1000, a first one of SH14 and SH54 in the hybrid filter 1100, or a first one of SH16 and SH56 in the hybrid filter 1500) that includes a diaphragm comprising a portion of a first piezoelectric layer that is over a cavity of the first XBAR and a first IDT on a surface of the first piezoelectric layer. The first XBAR is a diaphragm-based XBAR and an example of the first XBAR is shown in FIGS. 1A and 1B. In an example, referring to FIG. 1B, a dielectric layer (e.g., 124 in FIG. 1B) is located between a first substrate (e.g., 120 in FIG. 1B) of the first XBAR (e.g., 100′ in FIG. 1B) and the first piezoelectric layer (e.g., 110 in FIG. 1B), and the cavity (e.g., 140 in FIG. 1B) of the first XBAR (e.g., 100′ in FIG. 1B) is disposed in the dielectric layer (e.g., 124 in FIG. 1B).

The first IDT may include a pair of busbars with interleaved IDT fingers extending therefrom and, on the diaphragm, such as shown in FIG. 1A. The first XBAR may be connected between (i) one of an input (e.g., “IN” in FIGS. 8-11 and 15) and an output (e.g., “OUT” in FIGS. 8-11 and 15) of the hybrid bandpass filter and (ii) a ground of the hybrid bandpass filter. The cavity (e.g., the cavity 140 in FIG. 1A) may be disposed above a first substrate or being partially disposed in the first substrate. The plurality of series acoustic resonators and the plurality of shunt acoustic resonators includes at least one solidly-mounted XBAR (SM-XBAR) such as shown in FIG. 2E that includes a portion of a second piezoelectric layer that is solidly mounted over a second substrate with a Bragg reflector (e.g., the Bragg reflector 240) disposed therebetween and a second IDT on a surface of the second piezoelectric layer. The second IDT includes a pair of busbars with interleaved IDT fingers extending therefrom and on the second piezoelectric layer.

In an example, the plurality of shunt acoustic resonators further includes another XBAR, e.g., a second XBAR (e.g., a second one of SH1′ and SH5′ in the hybrid filter 800, a second one of SH1″ and SH5″ in the hybrid filter 900, a second one of SH1′″ and SH5′″ in the hybrid filter 1000, a second one of SH14 and SH54 in the hybrid filter 1100, or a second one of SH16 and SH56 in the hybrid filter 1500). The second XBAR is different from the first XBAR. The second XBAR includes a diaphragm comprising a portion of a third piezoelectric layer that is over a cavity of the second XBAR and a third IDT on a surface of the third piezoelectric layer. The second XBAR is a diaphragm-based XBAR and an example of the second XBAR is shown in FIG. 1A. The third IDT includes a pair of busbars with interleaved IDT fingers extending therefrom and on the diaphragm of the second XBAR, the cavity of the second XBAR is disposed above a third substrate or is partially disposed in the third substrate. The second XBAR is connected between (i) another one of the input (e.g., “IN” in FIGS. 8-11 and 15) and the output (e.g., “OUT” in FIGS. 8-11 and 15) of the bandpass filter and (ii) the ground of the bandpass filter.

In an example, the plurality of series acoustic resonators includes a third XBAR (e.g., one of SE1′″ and SE4′″ in the hybrid filter 1000, one of SE1₄ and SE4₄ in the hybrid filter 1100, or one of SE1₅ and SE4₅ in the hybrid filter 1200). The third XBAR is a diaphragm-based XBAR and an example of the third XBAR is shown in FIG. 1A. The third XBAR includes a diaphragm comprising a portion of a fourth piezoelectric layer that is over a cavity of the third XBAR and a fourth IDT on a surface of the fourth piezoelectric layer. The fourth IDT includes a pair of busbars with interleaved IDT fingers extending therefrom and on the diaphragm of the third XBAR. The cavity of the third XBAR is disposed above a fourth substrate or is partially disposed in the fourth substrate. In an example, the third XBAR is connected between (i) one of the input (e.g., “IN”) and the output (e.g., “OUT”) of the bandpass filter and (ii) a node of the bandpass filter, and the node of the bandpass filter is different from the input and the output of the bandpass filter. Referring to FIG. 10, the third XBAR may be SE1′″ and is connected between the “IN” of the bandpass filter and a node 1001 that is between SE1′″ and SE2′″.

In an example, a quality factor (e.g., a Q-factor such as Qm or QC0) of the first XBAR (e.g., a diaphragm-based XBAR) is greater than a quality factor of the SM-XBAR, such as shown in Table 2. In an example, quality factors of the first XBAR and the third XBAR are greater than a quality factor of the SM-XBAR, such as shown in Table 2.

In an example, a quality factor of the first XBAR (e.g., SH1₆ or SH5₆ in FIG. 15) is substantially identical to a quality factor of the SM-XBAR (e.g., one of SE1₆ to SE4₆ in FIG. 15), such as shown in Table 5.

Throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bandpass filter comprising:
an input port and an output port;
a plurality of series acoustic resonators connected between the input port and the output port; and
a plurality of shunt acoustic resonators,
wherein the plurality of shunt acoustic resonators includes a first transversely-excited film bulk acoustic resonator (XBAR) that includes a diaphragm comprising a portion of a first piezoelectric layer that is over a cavity of the first XBAR and a first interdigital transducer (IDT) on a surface of the first piezoelectric layer, the first IDT comprising a pair of busbars with interleaved fingers extending therefrom and on the diaphragm,
wherein the first XBAR is connected between (i) a node directly between a first series acoustic resonator of the plurality of series acoustic resonators and the input port, and (ii) a ground of the bandpass filter, and
wherein the plurality of series acoustic resonators and the plurality of shunt acoustic resonators includes at least one solidly-mounted XBAR (SM-XBAR) that includes a portion of a second piezoelectric layer that is solidly mounted over a substrate with a Bragg reflector disposed therebetween and a second IDT on a surface of the second piezoelectric layer, the second IDT comprising a pair of busbars with interleaved fingers extending therefrom and on the second piezoelectric layer.

2. The bandpass filter of claim 1, wherein:
the plurality of shunt acoustic resonators further includes a second XBAR,
the second XBAR includes a diaphragm comprising a portion of a third piezoelectric layer that is over a cavity of the second XBAR and a third IDT on a surface of the third piezoelectric layer, the third IDT comprising a pair of busbars with interleaved fingers extending therefrom and on the diaphragm of the second XBAR, the cavity of the second XBAR being disposed above the substrate or being partially disposed in the substrate, and
the second XBAR is connected between (i) a node directly between a last series acoustic resonator of the plurality of series acoustic resonators and the output port, and (ii) the ground of the bandpass filter.

3. The bandpass filter of claim 1, wherein:
the plurality of series acoustic resonators includes a third XBAR, and
the third XBAR includes a diaphragm comprising a portion of a fourth piezoelectric layer that is over a cavity of the third XBAR and a fourth IDT on a surface of the fourth piezoelectric layer, the fourth IDT comprising a pair of busbars with interleaved fingers extending therefrom and on the diaphragm of the third XBAR, the cavity of the third XBAR being disposed above the substrate or being partially disposed in the substrate.

4. The bandpass filter of claim 3, wherein the third XBAR is connected between (i) one of the input port and the output port of the bandpass filter and (ii) a node of the bandpass filter, the node of the bandpass filter being different from the input port and the output port of the bandpass filter.

5. The bandpass filter of claim 1, wherein a quality factor of the first XBAR is greater than a quality factor of the SM-XBAR.

6. The bandpass filter of claim 4, wherein quality factors of the first XBAR and the third XBAR are greater than a quality factor of the SM-XBAR.

7. The bandpass filter of claim 1, wherein a quality factor of the first XBAR is substantially identical to a quality factor of the SM-XBAR.

8. The bandpass filter of claim 1, further comprising a dielectric layer disposed between the substrate of the first XBAR and the first piezoelectric layer, wherein the cavity of the first XBAR is in the dielectric layer.

9. The bandpass filter of claim 1, wherein, for each of the plurality of series acoustic resonators and the plurality of shunt acoustic resonators, the piezoelectric layer and the IDT are configured such that a radio frequency signal applied to the IDT excites a primary shear acoustic mode in the piezoelectric layer in which acoustic energy propagates along a direction substantially orthogonal to front and back surfaces of the piezoelectric layer and that is transverse to a direction of an electric field created by the interleaved of fingers.

10. The bandpass filter of claim 1, wherein the first piezoelectric layer is the second piezoelectric layer.

11. The bandpass filter of claim 1, wherein:
the plurality of series acoustic resonators and the plurality of shunt acoustic resonators are all disposed on a single chip,
at least a portion of the plurality of series acoustic resonators have a stack thickness that is smaller than a stack thickness of at least a portion of the plurality of shunt acoustic resonators, and
the portion of the plurality of series acoustic resonators includes the at least one SM-XBAR, and the portion of the plurality of shunt acoustic resonators incudes the first XBAR.

12. The bandpass filter of claim 11, wherein the first piezoelectric layer of the first XBAR is thicker than a thickness of the second piezoelectric layer.

13. The bandpass filter of claim 11, wherein the Bragg reflector of the at least one SM-XBAR extends across the single chip in a planar direction and excludes an etched region to form the cavity of the first XBAR.

14. A bandpass filter comprising:
a plurality of bulk acoustic wave resonators comprising a first subset of bulk acoustic wave resonators and a second subset of bulk acoustic wave resonators;
a first chip comprising the first subset of bulk acoustic wave resonators;
a second chip comprising the second subset of bulk acoustic wave resonators; and
a circuit card coupled to the first chip and the second chip and including at least one electrical connection between the first subset of bulk acoustic wave resonators of the first chip and the second subset of bulk acoustic wave resonators of the second chip,
wherein the plurality of bulk acoustic wave resonators includes:
a plurality of series acoustic resonators connected in series between an input and an output of the bandpass filter; and
a plurality of shunt acoustic resonators that are each connected, respectively, between ground and a node between a pair of the series acoustic resonators or directly between the ground and a node between one of the series acoustic resonators and either the input or the output,
wherein the plurality of shunt acoustic resonators includes at least one transversely-excited film bulk acoustic resonator (XBAR) that comprises a first piezoelectric layer including a diaphragm that is over a cavity and a first interdigital transducer (IDT) on a surface of the diaphragm that includes a pair of busbars with interleaved fingers extending therefrom, and
wherein the plurality of series acoustic resonators includes at least one solidly-mounted XBAR (SM-XBAR) that includes a second piezoelectric layer that is solidly mounted over a substrate with a Bragg reflector disposed therebetween and a second IDT on a surface of the second piezoelectric layer that includes a pair of busbars with interleaved IDT fingers extending therefrom.

15. The bandpass filter of claim 14, wherein the first subset of bulk acoustic wave resonators of the first chip comprises the plurality of series acoustic resonators, and the second subset of bulk acoustic wave resonators of the second chip comprises the plurality of shunt acoustic resonators.

16. The bandpass filter of claim 15, wherein the first subset of bulk acoustic wave resonators each have a stack thickness that is smaller than a stack thickness of the second subset of bulk acoustic wave resonators.

17. The bandpass filter of claim 14, wherein the first subset of bulk acoustic wave resonators of the first chip includes the at least one SM-XBAR, and the second subset of bulk acoustic wave resonators of the second chip includes the at least one XBAR.

18. The bandpass filter of claim 14, wherein:
the plurality of shunt acoustic resonators further includes another XBAR that includes a third piezoelectric layer having a diaphragm that is over a cavity and a third IDT on a surface of the third piezoelectric layer and that includes a pair of busbars with interleaved IDT fingers extending therefrom, and
the plurality of series acoustic resonators includes another XBAR that includes a fourth piezoelectric layer having a diaphragm that is over a cavity and a fourth IDT on a surface of the fourth piezoelectric layer and including a fourth IDT having a pair of busbars with interleaved IDT fingers extending therefrom.

19. The bandpass filter of claim 14, wherein, for each of the plurality of series acoustic resonators and the plurality of shunt acoustic resonators, the respective piezoelectric layer and the respective IDT are configured such that a radio frequency signal applied to the IDT excites a primary shear acoustic mode in the piezoelectric layer in which acoustic energy propagates along a direction substantially orthogonal to front and back surfaces of the piezoelectric layer and that is transverse to a direction of an electric field created by the interleaved of fingers.

20. The bandpass filter of claim 14, wherein the first piezoelectric layer is the second piezoelectric layer.
